(19) United States
(12) Patent Application Publication
(10) Pub. No.: US 2016/0181325 A1
(43) Pub. Date: Jun. 23, 2016

(54) High pixel count short-wave to infrared image sensor

(71) Applicants: Paul Johnson, El Cajon, CA (US); Lawrence Sverdrup, Poway, CA (US)

(72) Inventors: Paul Johnson, El Cajon, CA (US); Lawrence Sverdrup, Poway, CA (US)

(21) Appl. No.: 14/544,326

(22) Filed: Dec. 23, 2014

(51) Int. Cl. H01L 27/30; H01L 51/42

(52) U.S. Cl. CPC H01L 27/307; H01L 51/426; H01L 51/0046

(57) ABSTRACT

A CMOS image sensor combining CMOS read-out integrated circuits (ROICs) and photodiode on active pixel (POAP) technology with quantum dot (PbS-CQD) detector material. This approach provides sensors and systems that are easily manufacturable with high yields The approach dramatically lowers the cost per pixel, reduces the pixel size, and increases the pixel count of SWIR sensors and cameras. The PbS-CQD detector material provides optical performance approaching that of InGaAs, and outperforms it in some respects. PbS-CQD detectors include multi-layered conformal thin-films, applied to the ROICs in liquid form. The films are perfectly suited for application over wide surface areas, limited only by wafer or substrate size.

### CROSS REFERENCE TO RELATED APPLICATIONS

This application claims the benefit of Ser. No. 61/964,124 filed Dec. 23, 2013.

### FIELD OF THE INVENTION

The present invention relates to imaging sensors and systems and in particular to high pixel count short wave infrared imaging sensors and systems.

### BACKGROUND OF THE INVENTION

### Quantum Dots

A quantum dot crystal is a nanocrystal made of semiconductor materials that are small enough to display quantum mechanical properties. The electronic properties of these materials are intermediate between those of bulk semiconductors and of discrete molecules or atoms. Quantum dots were discovered in the early 1980s. Researchers have studied applications for quantum dots in transistors, solar cells, LEDs, and diode lasers. For example, U.S. Pat. No. 8,742,398 assigned to Research Triangle Institute, Int'l describes photodiodes including layers of Quantum dot material. They have also investigated quantum dots as agents for medical imaging and as possible qubits in quantum computing. Quantum dot semiconductors are semiconductors whose electronic characteristics are closely related to the size and shape of the individual crystal. Size and band gap are inversely related in quantum dots. For example, in fluorescent dye applications, emission frequencies increase as the size of the quantum dot decreases, resulting in a color shift from red to blue in the light emitted. Excitation and emission of quantum dot materials are therefore highly tunable. Because the size of the crystals can be controlled during synthesis, the conductive properties can be carefully controlled. Quantum dots of different sizes can be assembled into a gradient multi-layer nanofilm.

### Photodiode On Active Pixel (POAP) Image Sensors

Applicants' employer is the world leader at applying thin-film detector material to CMOS read-out integrated circuits (ROICs). For example U.S. Pat. No. 7,906,826 describes a many pixel image sensor capable of operating with as many as 10 million to 250 million pixels. That patent along with several parent patents are incorporated herein by reference. These devices were invented by applicants and their fellow workers many years ago as confirmed by a long list of patents and patent applications that are identified in the '826 patent. Initially the devices were developed for digital x-ray sensors (using Selenium thin film detector material) and the technology has since matured for use as visible light sensors, using amorphous Silicon (a-Si) thin films, and micro-crystalline Germanium (uC-Ge) thin films have been explored for Short-wave Infrared (SWIR) image sensors. FIG. 7 is a copy of FIG. 9 of prior art U.S. Pat. No. 7,906,826. In this sensor each pixel circuit comprises a charge collecting electrode 48 and three transistors (a reset transistor 20, a source follower transistor 24 and a readout transistor switch 26 as shown in FIG. 7 (which is a copy of FIG. 9 of the '826 patent). A photodiode layer of charge generating material located above the pixel circuits convert electromagnetic radiation into electrical charges. This photodiode layer defines an n-layer 42 an i-layer 44 and a p-layer 46. The sensor array also includes a transparent surface electrode located above the photodiode layer which in the preferred embodiment is held at a positive potential of about 5 volts. At reset the pixel circuit is discharged to a potential of close to ground potential. Charges collected on the pixel electrode during signal integration increase the pixel potential in proportion to the light intensity in the photodiode region above the pixel circuit. Light from a target is focused on the sensor. The extent of the increase in potential at each pixel is the pixel signal. The pixel signals of all of the pixels represent an image of the target region.

### SWIR Image Sensors and Systems

In recent years, much interest has developed for image sensing the SWIR spectral wavelength region (often defined as the spectral range between 1400 nm to 3000 nm but sometime considered to be the range between 1000 nm to 2700 nm), but current approaches to the development of high pixel count, uncooled, and low noise detectors have run into major obstacles where pixel sizes and counts are limited by hybridization techniques (bump-bonding), high dark currents, and low yields. Image sensor cost, yield, maximum pixel count, and minimum achievable pixel size are driven mainly by the manufacturing process in which a crystalline detector material (such as InGaAs) is bump-bonded to a CMOS ROIC. In this process, a small dot of Indium is placed at each pixel to achieve a deformable contact to the detector material as the detector material is physically pressed down onto the ROIC. The minimum size of the Indium bumps is approximately 10 mm, limiting the minimum pixel spacing (pixel pitch) to approximately 10 mm. The pressure required to physically deform the Indium bumps and make good electrical contacts between the detector material and the ROIC limits the maximum number of pixels to approximately 4 million.

What is needed is a SWIR imaging sensor and system capable of at least ten meagpixels of resolution that has small pixel pitch, and is manufacturable with high yield and low cost.

### SUMMARY OF THE INVENTION

The present invention combines CMOS read-out integrated circuits (ROICs) and photodiode on active pixel (POAP) technology with lead sulfide colloidal quantum dot (PbS-CQD) detector material. This approach provides sensors and systems that are easily manufacturable with high yields The approach dramatically lowers the cost per pixel, reduces the pixel size, and increases the pixel count of SWIR sensors and cameras. The PbS-CQD detector material provides optical performance approaching that of InGaAs, and outperforms it in some respects. PbS-CQD detectors include multi-layered conformal thin-films, applied to the ROICs in liquid form. The films are perfectly suited for application over wide surface areas, limited only by wafer or substrate size.

Electrical operation of the PbS CQD detector material in an image sensor application is almost identical to that of other materials previously employed in applicants' POAP sensors, but has the potential to provide high performance in the VIS-SWIR regions, and yield pixel counts in the range of ten to more than two hundred megapixels, with low dark currents and small pixel pitches. The cost of a sensor that employs a CQD thin film on CMOS ROIC can be potentially several orders of magnitude lower than the current InGaAs SWIR sensors; for example, less than $100/megapixel for CQD sensors vs. more than $40,000/megapixel for InGaAs. Moreover, it is possible to make a multi-million pixel SWIR sensor with smaller pixel size using the CQD thin film approach.

In preferred embodiments the high pixel count CMOS image sensor is specifically designed for spectral imaging in the range of between wavelengths of 1000 nm and 3000 nm. It includes a plurality of pixel arrays lithographically stitched together on a substrate to form a stitched array of at least 13 million pixels, each pixel in the stitched array comprising at least three transistor circuits and a pixel electrode. And it includes a plurality of readout circuits lithographically fabricated on the substrate and adapted to permit readout of electrical signals collected by the pixels in the stitched array of pixels. A continuous planar array of photo diode layer of charge generating material completely overlaps the stitched array of at least 13 million pixels wherein the planar photo diode layer is comprised of fullerene layer and a quantum dot layer applied in liquid form over the plurality of pixel arrays. Also the sensor includes a surface electrode in the form of a grid or thin transparent layer located above said continuous layer of charge generating material. Reset circuits are lithographically fabricated on the substrate and adapted to reset the at least 13 million pixels of said continuous pixel array after each readout of signals and to provide electrical potentials between said pixel electrodes and said surface electrode.

In preferred embodiments all of the pixels, readout circuits and reset circuits are substantially identical. Preferred embodiments may include larger numbers of pixels such as at least 36 million, 100 million and 250 million. Embodiments may include an intrinsic layer located between the fullerene layer and the Quantum dot layer.

In addition to the fabrication of image sensors for the SWIR spectral region, the present invention may employ quantum dots of larger dimensions as the detector material to provide optical response in the Mid-wave Infrared (MWIR, 3-5 mm wavelength) or Long-wave Infrared (LWIR, 8-12 mm wavelength) spectral regions.

### BRIEF DESCRIPTION OF THE DRAWINGS

FIG. 1 shows a basic structure of a POAP image sensor of the present invention

FIG. 2 shows a POAP image sensor featuring Quantum Dots as the detector material.

FIGS. 3A and 3B show a 6-Transistor CTIO pixel circuit and 3-Transistor pixel circuit.

FIGS. 4A and 4B show a 13 Mpixel and a 208 Mpixel ROICs fabricated from the same electrical design and mask set by using ‘stitching’ technology at the foundry.

FIGS. 5A and 5B show SWIR images from a sensor of the preferred embodiment using halogen lamp with 1200 nm long-pass filter illumination and 1550 LED illumination.

FIGS. 6A, 6B and 6C demonstrate that the response of the ROIC (without the QD detector material applied) to light from halogen lamp: with no filtering (6A), with 900 nm long-pass filtering (6B), and with 1200 nm long-pass filtering (6C).

FIG. 7 is a copy of FIG. 9 of prior art U.S. Pat. No. 7,906,826.

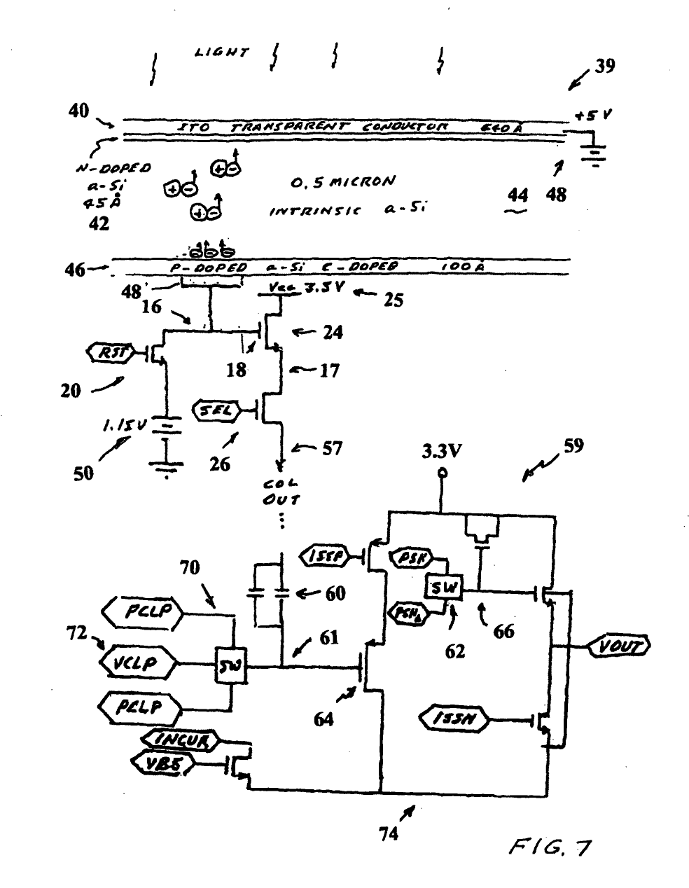

### DETAILED DESCRIPTION OF THE PREFERRED EMBODIMENTS

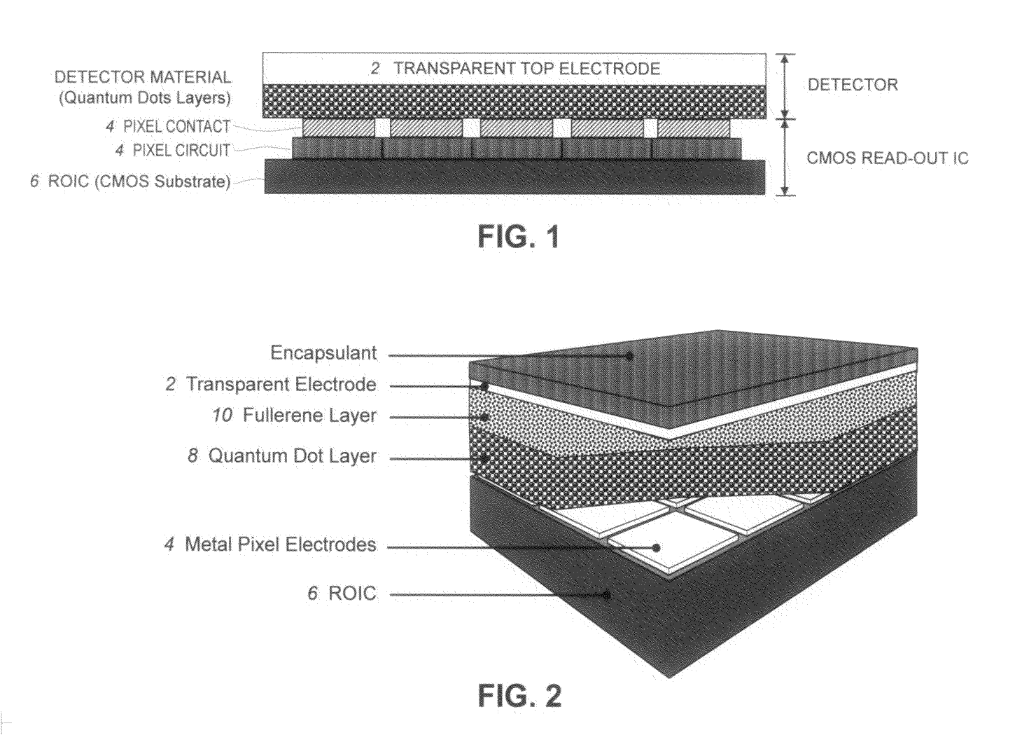

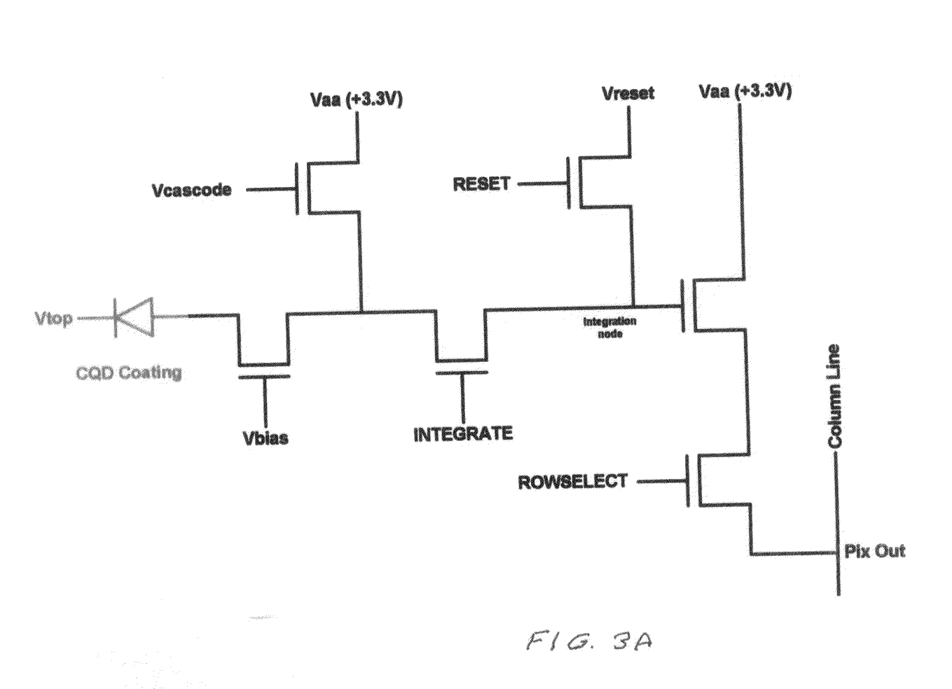

FIG. 1 illustrates the basic structure of a POAP image sensor, in which a thin film photodetector is applied to the surface of a CMOS readout array. A transparent top electrode 2 provides an electrical bias to the photo-detector top surface relative to pixel electrodes 4 in the ROIC 6. In a preferred embodiment of the invention, a prototype CMOS ROIC has been fabricated in 0.18 μm CMOS process at IBM Microelectronics, though other foundries such as Tower/Jazz, OnSemi, X-Fab, Cypress, and others are capable of producing similar ROICs. In a preferred embodiment, the detector layer is comprised of a multi-layer structure featuring a colloidally suspended Quantum Dot layer 8 as a light absorbing material, and forming a vertical PN diode structure at each pixel as illustrated in FIG. 2. In the preferred embodiment, the Quantum Dot layer 8 is applied to the ROIC by RTI International, Research Triangle Park, N.C., using quantum dots of specific diameter (˜80 nm) to provide good optical response at 1550 nm. The quantum dot layer is applied to the ROIC in liquid form using a spin-on technique well known to the semiconductor industry. A fullerene layer 10 is applied above the Quantum Dot layer in a similar manner. Together, the Quantum Dot layer and the Fullerene layer form a vertical NP diode structure. In preferred embodiments of the invention, the QD and Fullerene layers are applied to whole wafer (containing many ROICs) at once.

The application of the detector material layers in liquid form over the surface of the ROIC(s) eliminates the high cost and low yield of traditional bump-bonding detector approaches, and enables the fabrication of sensors with ten to several hundred megapixels. Applicants' prototype sensors were fabricated with 13 megapixels and 208 megapixels. In addition, raw material and fabrication costs for the QD detector are very low compared to traditional InGaAs bump-bonded detectors. Applicants estimate that the QD sensors can be fabricated at a cost of approximately about 0.02 percent of the cost of equivalent bump-bonded InGaAs sensors.

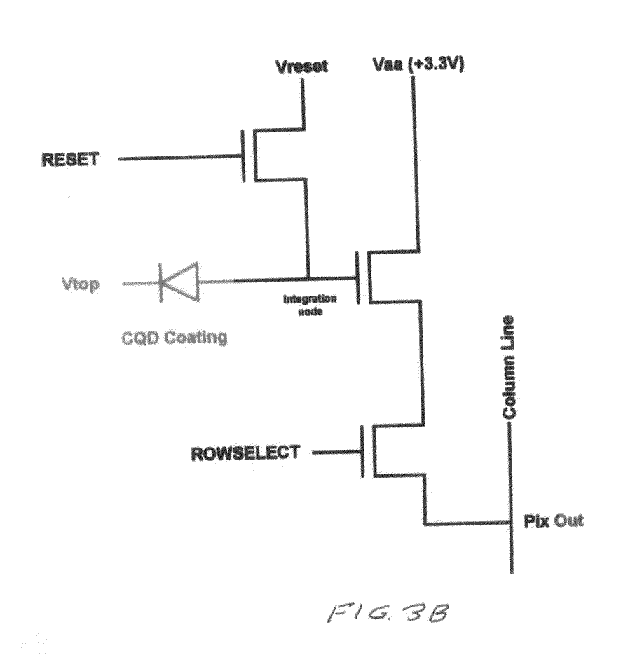

Operation of the QD detector at close to zero bias is preferable to achieve optimal performance (low leakage current), but is not required. In Applicants' prototype embodiment, a 3-transistor pixel circuit, shown in FIG. 3A is embedded in the CMOS ROIC underneath each pixel contact in the image sensor. An improved pixel circuit is shown in FIG. 3B in which a 6-Transistor CTIA amplifier is used to hold the detector bias close to a constant zero-volt potential.

In the prototype embodiments of the invention, the pixel pitch (center-center spacing of the pixels) is less than 3 mm, and a 3-transistor pixel circuit is used. In other embodiments of the invention the pixel pitch is 6 μm and a 6-transistor pixel circuit is used.

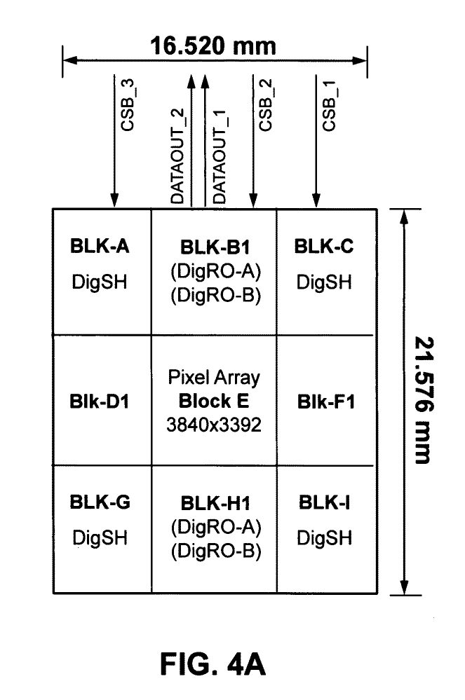

The ROIC employed for the preferred embodiment of the invention is fabricated using a ‘stitched’ process at the foundry. The ROIC is built by seamlessy piecing together 9 separate electrical designs to for the overall ROIC as shown in FIG. 4A. The nine individual designs are:
Top Left (BLK-A), Top Middle (BLK-B1), Top Right (BLK-C),
Left Middle (Blk-D1), Pixel Array (Block E), Right Middle (Blk-F1),
Bottom Left (BLK-G), Bottom Middle (BLK-H1), and Bottom Right (BLK-I).

Each individual block performs specific functions such as Timing and Control (corner blocks), Digitization (Top and Bottom Middle Blocks), Bias and Row Addressing (Left and Right Middle Blocks), and Pixel Circuitry (Pixel Array Block). In the preferred embodiment, the electrical designs and chip layouts are performed by Forza Silicon, Pasadena, Calif., and the ROIC mask set and CMOS wafers are fabricated by IBM Microelectronics, Burlington, Vt. Other ROIC layout vendors are available, such as Sensors Unlimited, L3, Raytheon, and others. Other CMOS ROIC fabrication vendors (foundries) are available, such as Tower/Jazz, OnSemi, Cypress Semiconductor, X-fab, TSMC, and others.

In the preferred embodiment, the ROIC contains a single pixel array of 3840×3392 pixels (13,025,280 pixels), shown in FIG. 4A. By using the same mask set and the stitching process at the foundry, ROICs of other formats may be composed by seamlessly stitching together the design pieces differently. A larger ROIC (208 megapixels), fabricated using the same mask set and electrical designs, but different stitching pattern is shown in FIG. 4B.

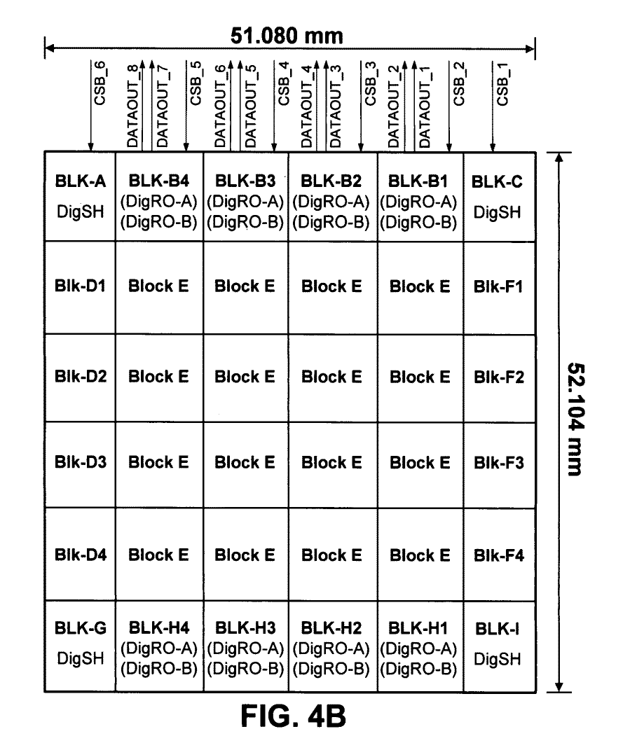

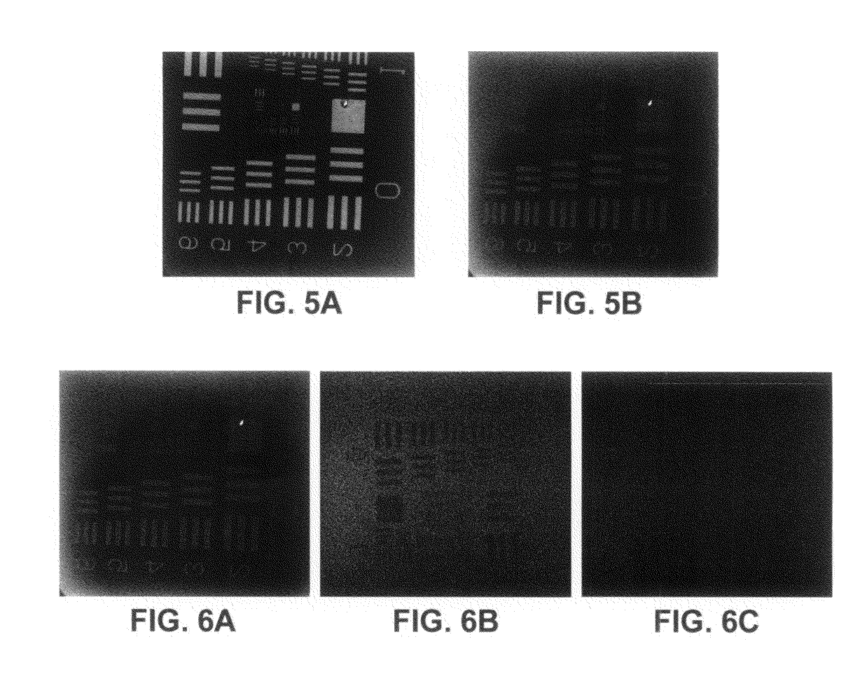

The FIGS. 4A and 4B sensors of the preferred embodiments are preferably wire-bonded to a printed circuit board. FIG. 5 shows images acquired using a sensor fabricated from a 13 Mpixel ROIC and QD thin film detector of the preferred embodiment under different SWIR illumination conditions. FIGS. 6A, 6B and 6C show images of the 13 Mpixel ROIC without the QD detector material on the surface, demonstrating that the SWIR optical performance is due solely to the QD detector material on the surface. FIG. 6A is an image of a target illuminated with a Halogen lamp with no filter producing fair image. In FIG. 6B the light is filtered with a 900 nm long pass filter producing a poor image of the target. In FIG. 6C the light is filtered with a 1200 nm long pass filter and no image is produced.

### Variations

The present invention has been described in terms of specific embodiments. Persons skilled in the sensor art will recognize that many variations and changes are possible within the scope of the present invention. For example, the sensors can be designed for a wide variety of wave lengths other than the specific wavelengths described in the specification. Most of the variations described in the two prior art patents (U.S. Pat. No. 8,742,398 and U.S. Pat. No. 7,906,862 referred to in the background section and incorporated herein) can be applied to the sensor generally described above.

What is claimed is:

1. A high pixel count CMOS image sensor for spectral imaging in the range of between wavelengths of 1000 nm and 3000 nm comprising:
A) a plurality of pixel arrays lithographically stitched together on a substrate to form a stitched array of at least 13 million pixels, each pixel in the stitched array comprising at least three transistor circuits and a pixel electrode,
B) a plurality of readout circuits lithographically fabricated on the substrate and adapted to permit readout of electrical signals collected by the pixels in the stitched array of pixels,
C) a continuous planar array of photo diode layer of charge generating material that completely overlaps the stitched array of at least 13 million pixels wherein the planar photo diode layer is comprised of:
1) fullerene layer and
2) a quantum dot layer applied in liquid form over the plurality of pixel arrays;
D) a surface electrode in the form of a grid or thin transparent layer located above said continuous layer of charge generating material; and
E) a plurality of reset circuits lithographically fabricated on said substrate and adapted to reset said at least 13 million pixels of said continuous pixel array after each readout of signals and to provide electrical potentials between said pixel electrodes and said surface electrode.

2. The sensor as in claim 1 wherein said continuous pixel array of at least 13 million pixels is comprised of a plurality of identical or substantially identical pixel arrays.

3. The sensor as in claim 1 wherein said readout circuits are comprised of a plurality of identical or substantially identical readout circuits, lithographically stitched together.

4. The sensor as in claim 1 wherein said reset circuits are comprised of a plurality of identical or substantially identical reset circuits, lithographically stitched together.

5. The sensor as in claim 1 wherein said continuous pixel array comprises is at least 36 million pixels.

6. The sensor as in claim 1 wherein said continuous pixel array comprises at least 100 million pixels.

7. The sensor as in claim 1 wherein said continuous pixel array comprises at least 250 million pixels.

8. The sensor as in claim 1 wherein said microcrystalline germanium layer and said an amorphous silicon layer are adapted to minimize changes in indexes of refraction.

9. The sensor as in claim 1 wherein the quantum dot layer is comprised of lead sulfide
